(19) United States
(12) Patent Application Publication
(10) Pub. No.: US 2006/0118934 A1
(43) Pub. Date: Jun. 8, 2006

(54) Multi-level semiconductor module and method for fabricating the same

(75) Inventors: Takahito Ishikawa, Kyoto (JP); Motoaki Satou, Kyoto (JP); Toshiyuki Fukuda, Kyoto (JP); Takeshi Kawabata, Osaka (JP); Masatoshi Shinagawa, Shiga (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/253,576

(22) Filed: Oct. 20, 2005

(30) Foreign Application Priority Data
Dec. 8, 2004 (JP) 2004-355539

(51) Int. Cl. H01L 23/02

(52) U.S. Cl. 257/680

(57) ABSTRACT

A multi-level semiconductor module according to the present invention is formed by alternately stacking resin boards and sheet members. Each of the resin boards is provided with a semiconductor device. The module includes: a rigid plate provided on one of the sheet members located at the top and having a heat dissipation efficiency higher than those of the resin boards and the sheet members; and a through buried conductor penetrating the resin boards and the sheet members and being in contact with the rigid plate.

### BACKGROUND OF THE INVENTION

The present invention relates to three-dimensional multi-level semiconductor modules formed by alternately stacking sheet members and resin boards on which semiconductor devices are mounted and also relates to methods for fabricating the modules.

With demands for size reduction and performance improvement of various electronic devices such as cellular phones and digital cameras, multi-level semiconductor modules formed by stacking and uniting a plurality of electronic components, especially semiconductor devices, have been proposed.

For example, to achieve density increase and thickness reduction of a multi-level semiconductor module, a multi-level semiconductor module formed by alternately stacking interlayer members and circuit boards provided with semiconductor devices and then pressing the stacked structure with heat has been proposed (see, for example, Japanese Unexamined Patent Publication No. 15-218273). Specifically, circuit boards on which semiconductor devices have been mounted beforehand and interlayer members having openings capable of accommodating the semiconductor devices are alternately stacked with adhesive layers interposed therebetween, and then this stacked structure is pressed with heat. This makes the semiconductor devices buried in the openings of the interlayer members, so that electrical connection is established between the semiconductor devices via conductor posts formed on the interlayer members. In this structure, the distance between the semiconductor devices is reduced, so that failures caused by wiring resistance and inductance are suppressed. As a result, in this multi-level semiconductor module, electric signals are transmitted at high speed without delay and the density and function of the printed board are enhanced and the thickness thereof is reduced.

In such a situation, techniques for reducing the thickness of semiconductor devices by polishing and techniques for mounting the thin semiconductor devices on boards with high yields have been recently developed, so that the number of levels in the stacked structure has been further increasing.

In addition, in a semiconductor memory, for example, the chip area increases as the memory capacity increases.

A multi-level semiconductor module formed principally of memories, a combination of a DRAM and an SRAM and a combination of a DRAM and a flash memory, for example, needs to be embedded and controlling semiconductor devices for controlling these memories also need to be mounted. In such a multi-level semiconductor module, the number of terminals connected to a mother board is greatly increased.

With size reduction, increase of the number of levels in the stacked structure, increase of the density in packaging and mounting multiple types of circuits to a chip having a larger size as described above, thermal stress and thermal resistance to boards according to capacity of heat generated from chips have been rapidly increasing. Accordingly, decrease of packaging accuracy due to a warp resulting from thermal stress and decrease of accuracy in signal transmission resulting from thermal resistance have become nonnegligible, so that that suppression of heat generation and heat dissipation in multi-level semiconductor module have become important tasks.

To suppress heat generation and dissipation in/from semiconductor-mounted boards, many applications for packaging methods in which a cooling member such as a radiator or a heat sink is attached to the back surface of a board and a metal medium for heat transfer is brought into contact with the cooling member have been filed for patents (see, for example, Japanese Unexamined Patent Publication No. 09-321188).

However, in any of the conventional methods described above, a cooling member is attached to a mother board in installing a semiconductor package to a set product. If similar cooling members are attached to boards provided with semiconductor devices at respective levels of a stacked structure, the number of components increases, so that the cost and thickness of the resultant multi-level semiconductor module greatly increase.

As in the conventional methods described above, if a multi-level semiconductor module is secondary packaged with a cooling member attached only to a mother board, it takes time to cool the multi-level semiconductor module from the bottom level through the top level. As a result, heat dissipation efficiency of the whole multi-level semiconductor module inevitably decreases.

### SUMMARY OF THE INVENTION

Objects of the present invention are prevention of a warp of stacked boards, reduction of thermal resistance and increase of lifetime of the boards by suppressing heat generation of the boards due to heat generation from semiconductor devices.

In an aspect of the present invention, a multi-level semiconductor module is a multi-level semiconductor module formed by alternately stacking resin boards and sheet members, and each of the resin boards is provided with a semiconductor device. This multi-level semiconductor module includes: an electrically-insulating rigid body provided on one of the sheet members located at the top and having a heat dissipation efficiency higher than those of the resin boards and the sheet members; and a through buried conductor penetrating the resin boards and the sheet members and being in contact with the electrically-insulating rigid body.

With this structure, when the multi-level semiconductor module is operated after being mounted on a mother board, heat generated from the semiconductor devices is dissipated into the air through the through buried conductor and the electrically-insulating rigid body. This enables heat dissipation to be performed in a time much shorter than that in a conventional multi-level semiconductor module. The multi-level semiconductor module in the aspect of the present invention has a very simple structure in which only the through buried conductor and the electrically-insulating rigid body are added to the structure of the conventional multi-level semiconductor module. Accordingly, costs of components and fabrication cost are reduced, and the thickness and the size can be reduced.

In addition, in this module, application of heat and pressure to the stacked structure is performed through the electrically-insulating rigid body having a high thermal conductivity, so that the resin boards and the sheet members are heated with a relatively uniform temperature distribution.

In the module, each of the resin boards may include: a mounting region on which a plurality of terminal electrodes connected to the semiconductor device are provided; and a peripheral region surrounding the mounting region, first buried conductors penetrating the resin board and a wiring pattern electrically connecting the first buried conductors to the terminal electrodes may be provided in the peripheral region of each of the resin boards, each of the sheet members may further include a resin core having a thickness larger than that of the semiconductor device and having an opening region larger than the mounting region, and a plurality of second buried conductors made of a conductive resin and located at positions corresponding to (i.e., coincident with, in plan view) the positions of the terminal electrodes may be provided in the resin core.

With this structure of the module, after the semiconductor devices have been mounted on the resin boards, a necessary electrical inspection and a necessary burn-in test are performed by using the wiring patterns provided on the surfaces of the resin boards accordingly, it is confirmed that these semiconductor devices are non-defective before the module is completed.

Preferably, in the module, the resin boards and the sheet members are alternately stacked and bonded together in such a manner that the positions of the terminal electrodes of the resin boards match the positions of the second buried conductors in the sheet members, and the through buried conductor penetrates one of the sheet members located at the top through one of the resin boards located at the bottom.

Preferably, in the module, the second buried conductors and the through buried conductor are capable of being compressed and deformed by application of pressure, and the through buried conductor is capable of being in contact with the electrically-insulating rigid body by application of pressure.

In the module, on a face of one of the resin boards located at the bottom opposite to a face thereof on which the semiconductor device is mounted, a plurality of external connection terminals for connecting the semiconductor device to external equipment may be provided. In this case, the module is mounted to a mother board using bumps or solder balls. The bumps or solder balls used as external connection terminals may be formed on the entire surface of the resin board or may be collectively formed on a given region.

Preferably, in the module, each of the sheet members further includes adhesive layers formed on both faces of the resin core and capable of being softened to be adhesive by application of heat, and the second buried conductors protrude from the both faces of the resin core and penetrate the adhesive layers.

In the module, a thin plate medium having a thermal conductivity higher than that of the sheet members may be interposed between each of the resin boards and an associated one of the sheet members, and the thin plate medium may have apertures each having a diameter larger than that of an associated one of the second buried conductors, at positions corresponding to the positions of the second buried conductors.

In particular, if a thin plate medium having a high thermal conductivity in the lateral direction, such as a graphite sheet, is bonded to the lower face of the resin board, heat propagating from the semiconductor device to the resin board through, for example, terminals is rapidly transferred to the through buried conductor. As a result, heat generated from the semiconductor device is more quickly dissipated to the outside.

In the module, the thickness of the resin core is larger than at least that of the semiconductor device in the opening region of each of the sheet members. Accordingly, after stacking and bonding, a gap is generated between the upper end face of the semiconductor device mounted on the resin board and the lower face of the resin board located on this semiconductor device. This causes heat generated from the semiconductor device in operation to be transferred only from the resin board through connection terminals. Alternatively, the opening region may have a thickness substantially equal to that of the semiconductor device so that a plurality of buried conductors having a high thermal conductivity are provided in the resin core in the opening region. In this case, the module may have a structure in which the sheet members exhibit elastic deformation to be in contact with the surfaces of the semiconductor devices. Alternatively, the module may have a structure in which an elastic body having a high thermal conductivity such that the elastic body is brought into contact with the upper end face of the semiconductor device by elastic deformation upon application of pressure and heat is bonded, in the opening region, to the lower face of the resin board placed on the sheet member or to the lower face of the thin plate medium. Such structures are able to promote heat conduction from the mounting faces of the semiconductor devices as well as heat conduction from the boards, so that heat generated from the semiconductor devices is more quickly dissipated to the outside.

In the module, the pitches of the first and second buried conductors may decrease toward the semiconductor device. In this case, heat propagating to the resin board by way of terminals or the like in operation of the semiconductor device can be quickly dissipated to the outside from a portion near the semiconductor device through the buried conductors.

In the module, the diameter of the second buried conductors in the sheet members in contact with the top and bottom resin boards may be smaller than that of the second buried conductors in the other sheet members.

In general, in application of pressure and heat to the stacked structure, pressure is not readily applied to a resin board and a sheet member near a center portion, so that a conductive resin material for forming the second buried conductors is not sufficiently compressed in apertures in some cases. However, if the diameter of the second buried conductors in a sheet member placed near the center portion is increased, the same resistance value is obtained as a whole. In addition, the increase of the diameter also increases thermal conductivity upon application of pressure, so that a delay in curing is avoided.

In the module, if the semiconductor device includes a terminal, the diameter of each of some of the first and second buried conductors connected to the terminal may be larger than that of each of the other first and second buried conductors not connected to the terminal. The “terminal” in this case is a predetermined terminal. In this structure, if the diameter of the first and second buried conductors connected to predetermined terminals of the semiconductor device is increased, the resistance value is reduced, so that deterioration of characteristics is prevented. For example, if the diameter of buried conductors connected to a terminal of a power supply line or a high-speed signal line is increased, voltage drops and signal rounding are less likely to occur. If voltage drops do not readily occur, Joule heat generated in buried conductors in using a multi-level semiconductor module is reduced, resulting in suppressing generation of heat inside the module.

In the module, a cooling medium may be fixed to the inside of the through buried conductor. As the cooling medium, a heat-electricity exchanger such as a Peltier device that is supplied with power from an external semiconductor-device operating power supply may be used. In such a case, it is possible not only to transfer heat generated from the semiconductor device to the through buried conductor through the resin board but also to cool heat generated from the resin board by using the cooling medium.

In a method for fabricating a multi-level semiconductor module in an aspect of the present invention, the resin boards and the sheet member are alternately stacked with the positions thereof adjusted such that the first buried conductors are in contact with the second buried conductors. In this structure, if a thin plate medium having a high thermal conductivity is inserted between the resin boards and the sheet members, the positions are adjusted such that the second buried conductors are not in contact with apertures of the thin plate medium. Then, after the top sheet member has been placed and through holes are formed using a mechanical drill or a carbon dioxide laser in a region of the resin board on which no wiring pattern is formed, through buried conductors may be formed by vapor-depositing a resin powder having a high thermal conductivity on the inside of the through holes. Thereafter, pressure and heat are applied to the electrically-insulating rigid body, so that the resin boards and the sheet members are bonded together to be electrically connected to each other. With this method, failures are less likely to occur even in stacking using resin boards whose reliability has been confirmed through inspections such as a burn-in test after mounting and, in addition, the degree of a warp of the resultant multi-level semiconductor module is reduced.

In the method described above, the degree of a warp occurring in the resin boards in bonding the resin boards and the sheet members together by application of pressure and heat may be previously obtained so that a material for the electrically-insulating rigid body is selected according to the amount.

With this method, in application of pressure and heat, the stack of the resin boards and the sheet members is heated with a relatively uniform temperature distribution. If the degree of a warp of the structure to which no rigid plate is attached is obtained and then a material compensating this warp is used for a rigid plate, the degree of the warp is further reduced. For example, in a case where the bottom of the stack of the resin boards and the sheet members in a predetermined shape has a convex shape, the use of a rigid plate having a large thermal expansion coefficient, for example, allows a warp to be absorbed. In the reverse case, i.e., in a case where the bottom has a concave shape, a rigid plate having a small thermal expansion coefficient is used. The rigid plate may be made of various materials such as metal, ceramic and resin. The material of the rigid plate may be appropriately selected.

### BRIEF DESCRIPTION OF THE DRAWINGS

FIG. 1 is a perspective view schematically illustrating an overall structure of a multi-level semiconductor module 1 according to a first embodiment of the present invention.

FIG. 2 is a cross-sectional view of the semiconductor module taken along the line A-A in FIG. 1.

FIGS. 3A through 3C are views for explaining a structure of a first resin board 3.

FIGS. 4A through 4C are views for explaining a structure of a sheet member 5.

FIGS. 5A through 5C are cross-sectional views illustrating process steps of fabricating the multi-level semiconductor module of the first embodiment.

FIGS. 6A through 6D are cross-sectional views illustrating process steps of fabricating the multi-level semiconductor module of the first embodiment.

FIGS. 7A through 7D are cross-sectional views illustrating process steps of fabricating the multi-level semiconductor module of the first embodiment.

FIG. 8 is a cross-sectional view schematically illustrating the stacked structure illustrated in FIG. 1 in a disassembled state.

FIG. 9 is a cross-sectional view illustrating a structure of a multi-level semiconductor module 100 according to a second embodiment of the present invention.

FIG. 10 is a plan view illustrating a structure of a first resin board 110 for use in a multi-level semiconductor module according to a third embodiment of the present invention.

FIG. 11 is a perspective view schematically illustrating an overall structure of a multi-level semiconductor module 200 according to a fourth embodiment of the present invention.

FIG. 12 is a cross-sectional view taken along the line A-A in FIG. 11.

### DETAILED DESCRIPTION OF THE INVENTION

### Embodiment 1

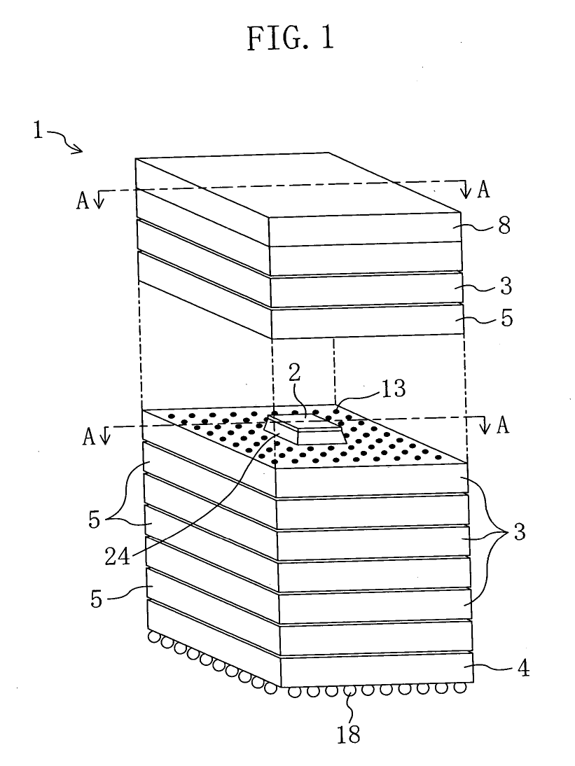

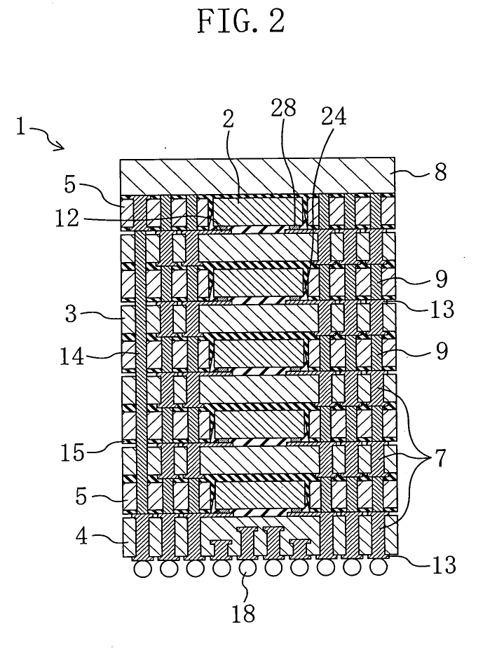

Hereinafter, a structure of a multi-level semiconductor module according to a first embodiment of the present invention will be described with reference to FIGS. 1, 2, 3A through 3C and 4A through 4C. FIG. 1 is a perspective view illustrating an overall structure of a multi-level semiconductor module 1 according to the first embodiment. FIG. 2 is a cross-sectional view of the multi-level semiconductor module taken along the line A-A in FIG. 1. For convenience of description, FIG. 1 illustrates only a part of the levels that is cut off in the thickness direction. In the drawings of the present invention, for convenience of making the drawings, the thicknesses and length, for example, of components might differ from those of actual components. The numbers and shapes of buried conductors and external connection terminals for external connection shown in the drawings differ from those of actual conductors and terminals, and are modified to be easily illustrated in the drawings.

As illustrated in FIG. 1, in the multi-level semiconductor module 1 of this embodiment, sheet members 5 and first resin boards 3 provided with semiconductor devices 2 are alternately stacked. One of the resin boards located at the bottom is refereed to as a second resin board 4 to be distinguished from the other first resin boards 3. A rigid plate 8 such as an aluminum plate exhibiting electrical insulation and excellent heat dissipation is provided on the upper face of one of the sheet members 5 located at the top, and solder balls 18 are provided on the lower face of the second resin board 4. The module of this embodiment is formed by stacking the first resin boards 3, the second resin board 4, the sheet members 5, the rigid plate 8 and the solder balls 18 and then uniting the stacked components by application of heat and pressure. In addition, as illustrated in FIG. 2, buried conductors 7 and 14 that are used only for heat dissipation, penetrate the first resin boards 3, the second resin board 4 and the sheet members 5 and have a high thermal conductivity are further provided.

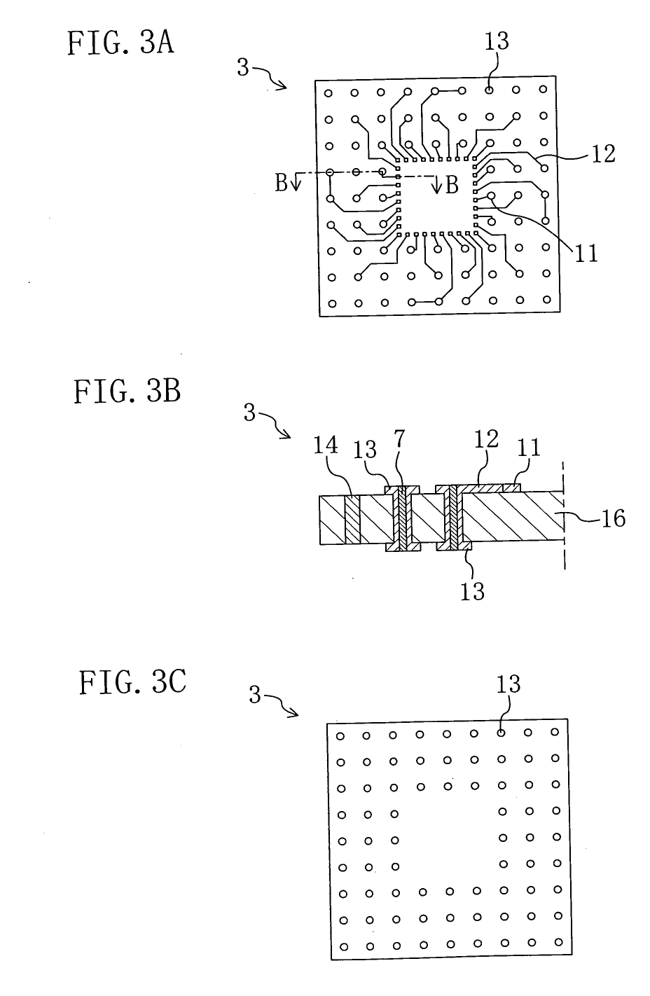

Now, the components will be more specifically described. FIGS. 3A through 3C are views for explaining a structure of the first resin boards 3. FIG. 3A is a top view, FIG. 3B is a cross-sectional view taken along the line B-B in FIG. 3A, and FIG. 3C is a bottom view. As illustrated in FIGS. 1 and 3A through 3C, each of the first resin boards 3 includes: a first resin base 16; a plurality of semiconductor-device connecting terminals 11 surrounding a region of the first resin base 16 on which a semiconductor device 2 is to be mounted; a plurality of first buried conductors 7 provided in the first resin boards 3 and located at the outside of the semiconductor-device connecting terminals 11; and a plurality of wires 12 connecting the semiconductor-device connecting terminals 11 and the associated first buried conductors 7.

A conductive resin material or a plated conductor is used as the first buried conductors 7. Connecting lands 13 are formed around both ends of the first buried conductors 7. Third buried conductors 14 are provided in a region not connected to the wires 12.

The thickness of each of the first resin boards 3 is in the range from 60 μm to 200 μm. Each of the first buried conductors 7 has a diameter of 0.15 mm to 0.5 mm and the first buried conductors 7 are arranged at a pitch of 0.3 mm to 0.75 mm. These components are appropriately designed within these ranges. The thickness of the second resin board 4 is preferably in the range from 100 μm to 300 μm and is larger than at least that of the first resin boards 3. The diameter and pitch of the first buried conductors 7 in the second resin board 4 are the same as those of the first buried conductors 7 in the first resin boards 3.

As illustrated in FIG. 2, the semiconductor devices 2 are connected to the semiconductor-device connecting terminals 11 (shown in FIG. 3B) on the first resin boards 3 and the second resin board 4 through electrode bumps 28, and the peripheral portions of the semiconductor devices 2 are protected by a searing resin 24. The searing resin 24 protects circuit surfaces of the semiconductor devices 2 against external environment and absorbs a thermal distortion, for example. The thickness of each of the semiconductor devices is preferably in the range from 30 μm to 150 μm.

The second resin board 4 has a structure similar to that of the first resin boards 3 as a whole. On the lower face of the second resin board 4, solder balls 18 in contact with lands (not shown), serving as connection terminals connected to a mother board (not shown), are formed at given intervals. Solder bonding to the mother board is performed using these solder balls 18.

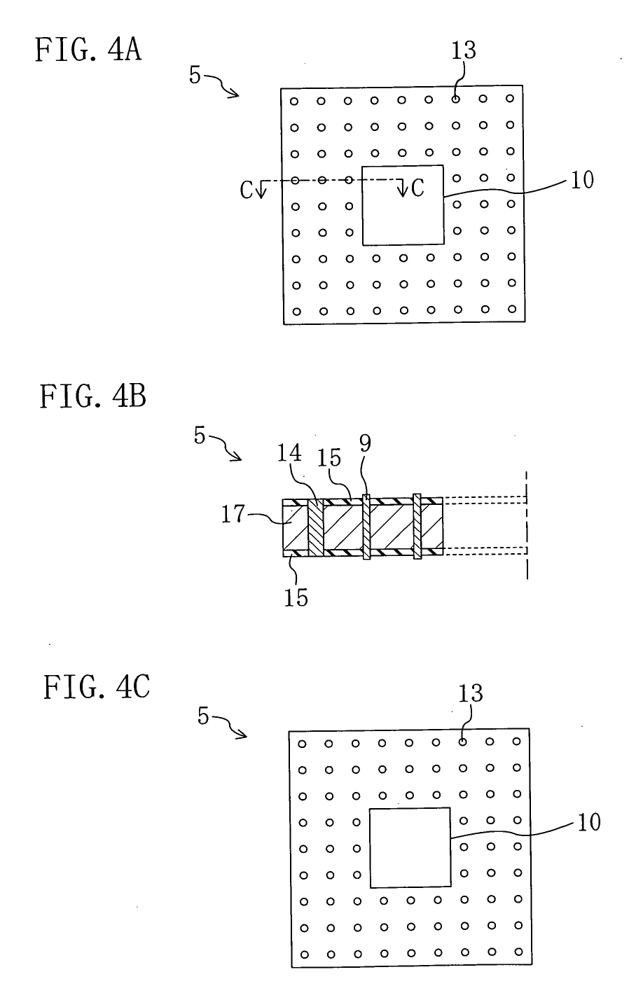

FIGS. 4A through 4C are views for explaining a structure of the sheet members 5. FIG. 4A is a top view, FIG. 4B is a cross-sectional view taken along the line C-C in FIG. 4A, and FIG. 4C is a bottom view. As illustrated in FIGS. 4A through 4C, each of the sheet members 5 includes: adhesive layers 15 formed on upper and lower faces of a second resin base 17; second buried conductors 9 located at positions corresponding to the positions of the first buried conductors 7 in the first resin boards 3 in plan view and made of a conductive resin material; and an opening 10 provided in a center region and capable of accommodating a semiconductor device 2. The second buried conductors 9 project from the surfaces of the sheet members 5 to a given height. The second buried conductors 9 are semi-cured before stacking, and are compressed and cured by application of pressure and heat after the stacking. The second buried conductors 9 are electrically connected to the first buried conductors 7 in the first resin boards 3 and the second resin board 4 mainly by mechanical contact.

The thickness of the second resin base 17 is in the range from 45 μm to 200 μm. The adhesive layers 15 each having a thickness from 10 μm to 100 μm are provided on both faces of the second resin base 17. The diameter and pitch of the second buried conductors 9 are the same as those of the first buried conductors 7 in the first resin boards 3.

Third buried conductors 14 that are not electrically connected to the wires 12 even when being brought into mechanical contact with the first resin boards 3 (shown in FIGS. 3A through 3C, for example) are provided at positions corresponding to (i.e., coincident with, in plan view) the positions of part of the first buried conductors 7 (shown in FIG. 3B) not connected to the wires 12 in the sheet members 5. Unlike the second buried conductors 9, the third buried conductors 14 do not project from the surfaces and have a structure similar to that of the first buried conductors 7 except that no connecting lands 13 (shown in FIG. 3B) are provided around the third buried conductors 14. The third buried conductors 14 may be made of a conductive material or plated conductors as the first buried conductors 7, but are preferably made of conductors especially having a high thermal conductivity.

Then, the rigid plate 8 made of, for example, aluminum having a high thermal conductivity and electrical insulation is stacked on the top sheet member 5 such that the rigid plate 8 is in contact with the third buried conductors 14 and the dimensions of the rigid plate 8 coincide with those of the first resin boards 3, the second resin board 4 and the sheet members 5 in plan view.

With the foregoing arrangement, the multi-level semiconductor module 1 of this embodiment is formed. The first resin boards 3, the second resin board 4 and the sheet members 5 may be made of the same material such as a glass epoxy resin or an aramid resin. Alternatively, the first and second resin boards 3 and 4 and the sheet members 5 may be made of different materials. For example, a glass epoxy resin may be used for the first resin boards 3 and the second resin board 4 and an aramid epoxy resin may be used for the sheet members 5. In either case, the outer dimensions of the first resin boards 3, the second resin board 4 and the sheet members 5 are the same in plan view.

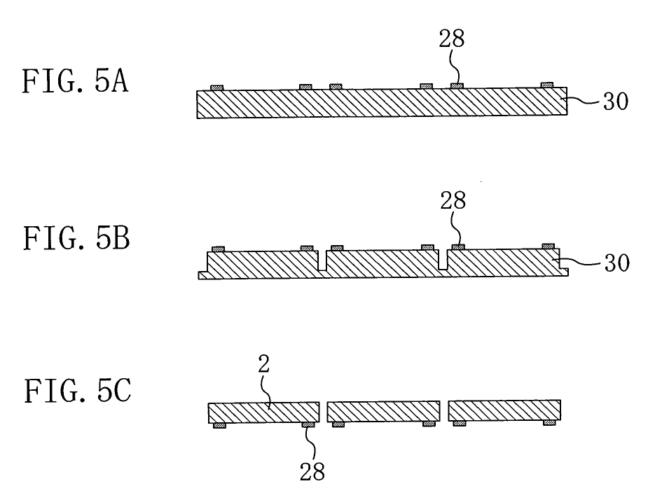

Now, a method for fabricating a multi-level semiconductor module according to this embodiment will be described with reference to FIGS. 5A through 8. FIGS. 5A through 8 are cross-sectional views illustrating process steps of fabricating a multi-level semiconductor module of the first embodiment.

In the fabrication method of this embodiment, first, in a process step illustrated in FIG. 5A, electrode bumps 28 are formed by electroplating or stud bump bonding (SBB) on bonding pads on the principal surfaces of a plurality of semiconductor devices 2 in a semiconductor wafer 30 that has been subjected to a circuit formation process necessary for the semiconductor devices 2. Then, in a process step illustrated in FIG. 5B, the semiconductor wafer 30 is cut halfway by dicing or by using a laser from the principal surface in a separation zone thereof located between the semiconductor devices 2. Thereafter, in a process step illustrated in FIG. 5C, a process such as chemical etching, back-face polishing, plasma etching or a process using these processes is performed on the back face of the semiconductor wafer 30 until the thickness of the semiconductor wafer 30 is reduced to the range from 30 μm to 150 μm, thereby separating the semiconductor devices 2 from each other.

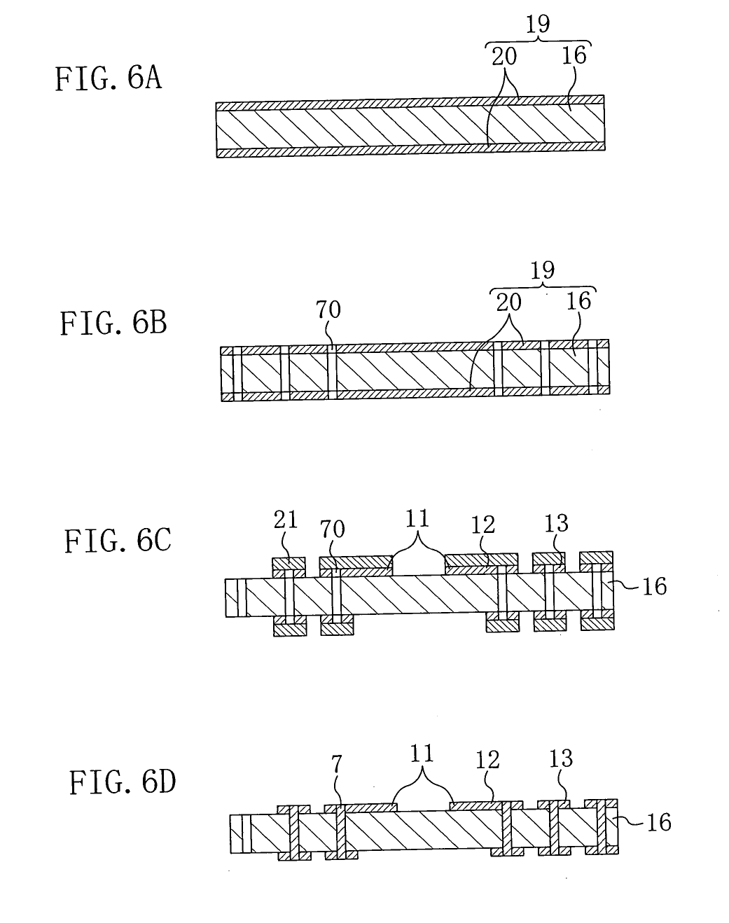

Now, an example of a method for fabricating the first and second resin boards 3 and 4 for mounting the semiconductor devices 2 will be described with reference to FIG. 6A through 6D. Hereinafter, one of the first resin boards 3 is used as an example. In the following example, a glass epoxy resin is used for the first resin base 16 and copper foil is used for the wires 12 and the connecting lands 13.

First, in a process step illustrated in FIG. 6A, a two-side copper-clad board 19 formed by covering both faces of the first resin base 16 with copper foil 20 is prepared. In the two-side copper-clad board 19, the copper foil 20 having a thickness of 15 μm is bonded to both faces of the first resin base 16 having a thickness of 70 μm, so that the total thickness of the two-side copper-clad board 19 is 100 μm.

Then, in a process step illustrated in FIG. 6B, through holes 70 are formed in portions of the two-side copper-clad board 19 with a laser.

Subsequently, in a process step illustrated in FIG. 6C, photosensitive films 21 are attached to both faces of the two-side copper-clad board 19, and photolithography and etching are performed, thereby forming semiconductor-device connecting terminals 11, connecting lands 13 and wires 12 connecting the semiconductor-device connecting terminals 11 and the connecting lands 13 on one face of the first resin base 16. Connecting lands 13 are also formed on another face of the first resin base 16. Thereafter, the photosensitive films 21 are peeled off from the both faces.

Thereafter, in a process step illustrated in FIG. 6D, the through holes 70 are filled with, for example, a conductive paste (not shown). This conductive paste is cured with heat, thereby obtaining a first resin board 3 including first buried conductors 7. The first resin boards 3 and the second resin board 4 are not necessarily formed by the method described above and may be formed by a method for forming a usual two-side circuit board and by using usual materials. However, it should be noted that some of the through holes 70 arranged in a region not connected to the wires 12 are not filled with the 10 conductive paste and a resin material (not shown) having a high thermal conductivity, for example, is vapor-deposited or applied onto the surface.

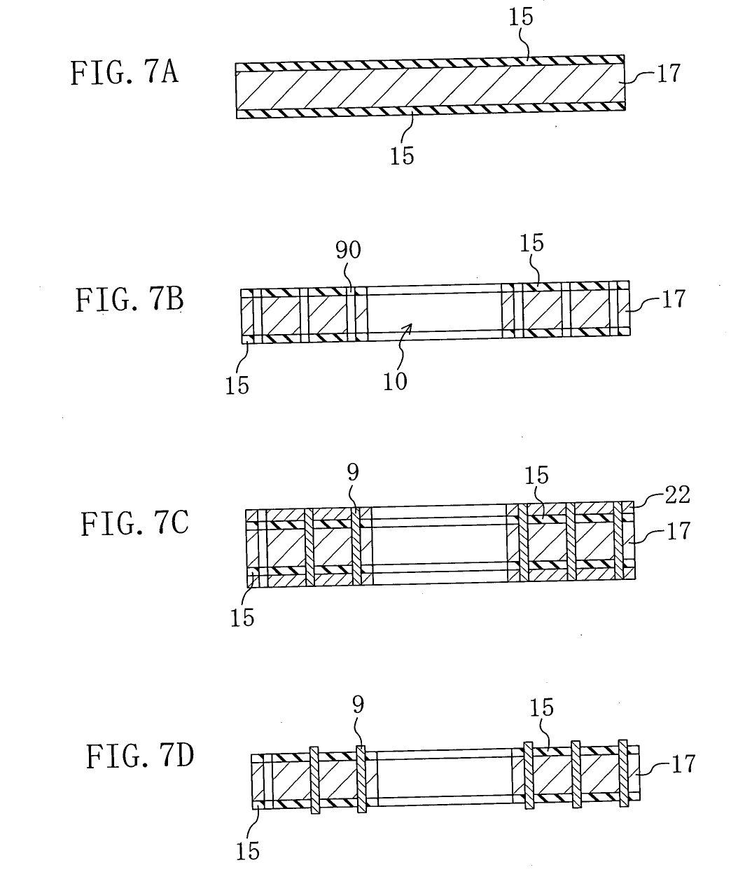

Now, a method for forming sheet members 5 will be described with reference to FIGS. 7A through 7D. First, in a process step illustrated in FIG. 7A, a second resin base 17 having a thickness larger than that of a semiconductor device 2 and made of, for 15 example, a glass fabric epoxy resin is prepared. If the thickness of the semiconductor device 2 is 75 μm, the thickness of the second resin base 17 is preferably about 100 μm.

Thereafter, adhesive layers 15 made of an epoxy prepreg or a thermosetting adhesive layer and each having a thickness of about 15 μm are formed on both faces of the second resin base 17.

Then, in a process illustrated in FIG. 7B, through holes 90 are formed in given portions of the second resin base 17 and the adhesive layers 15 with a laser.

Simultaneously with the formation of the through holes 90, an opening 10 capable of accommodating the semiconductor device 2 is formed in a center region of the second resin base 17.

Then, in a process step illustrated in FIG. 7C, masking films 22 are attached to both faces of the second resin base 17, and then the through holes 90 are filled with a conductive paste by, for example, screen printing, thereby forming second buried conductors 9. Some of the through holes 90 in a region not connected to the wires 12 (shown in FIG. 2, for example) are not filled with the conductive paste, and a resin material (not shown) having a high thermal conductivity, for example, is vapor-deposited or applied onto the surface.

Subsequently, in a process step illustrated in FIG. 7D, the conductive paste is dried, and then the masking films 22 are peeled off, thereby forming a sheet member 5. The second buried conductors 9 filled with the conductive paste are still semi-cured, so that the second buried conductors 9 have the property of being compressed and cured by application of pressure and heat.

Now, a process of mounting semiconductor devices 2 on the first and second resin boards 3 and 4 will be described. To mount the semiconductor devices 2, the electrode bumps 28 (shown in FIG. SC, for example) of the semiconductor devices 2 are bonded to the semiconductor-device connecting terminals 11 (shown in FIG. 6D, for example) of the first resin boards 3 and the second resin board 4 using, for example, solder or a conductive resin. Then, a sealing resin 24 is applied and cured so that gaps formed after the bonding are filled therewith. In this manner, the semiconductor devices 2 are mounted on the first resin boards 3 and the second resin board 4. If an electrical inspection and a burn-in test are performed in subsequent processes, a semiconductor module having reliability similar to that of a usual packaged semiconductor module is obtained.

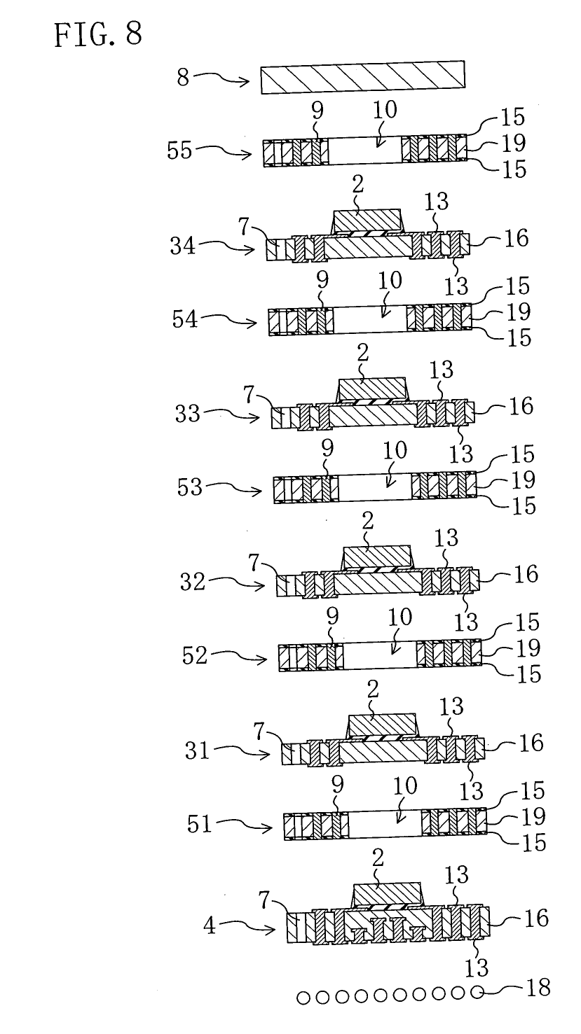

Then, a process of stacking and uniting the sheet members 5 and the first and second resin boards 3 and 4 on which the semiconductor devices 2 are mounted will be described with reference to FIG. 8. FIG. 8 is a cross-sectional view schematically illustrating the stacked structure illustrated in FIG. 1 in a disassembled state. In the following description, for simplicity, the first resin boards 3 are individually referred to as a first-level first resin board 31, a second-level first resin board 32, a third-level first resin board 33 and a fourth-level first resin board 34. Likewise, the sheet members 5 are individually referred to as a first-level sheet member 51, a second-level sheet member 52, a third-level sheet member 53, a fourth-level sheet member 54 and a fifth-level sheet member 55.

As illustrated in FIG. 8, the second resin board 4 is placed at the bottom and the first-level sheet member 51 and the first-level first resin board 31 are placed in this order on the second resin board 4. The second-level sheet member 52, the second-level first resin board 32, the third-level sheet member 53, the third-level first resin board 33, the fourth-level sheet member 54, the fourth-level first resin board 34, the fifth-level sheet member 55 and the top rigid plate 8 are stacked in this order.

These components are stacked such that the semiconductor devices 2 mounted on the first and second resin boards 3 and 4 overlap each other in plan view. The first resin boards 3 and the second resin board 4 are placed such that the semiconductor devices 2 are held in the openings 10 of the sheet members 5. The connecting lands 13 of the first resin boards 3 and the second resin board 4 are accurately positioned so as to be in contact with the projections of the second buried conductors 9 in the sheet members 5.

In addition, the rigid plate 8 having a shape similar to that of the sheet members 5 and made of, for example, an aluminum plate exhibiting electrical insulation and a high thermal conductivity is placed on the top sheet member 55 so as to be in contact with the second buried conductors 9 and the third buried conductors 14 (shown in FIG. 2, for example) of the sheet member 55. The top rigid plate 8 is not necessarily an aluminum plate and may be made of an electrical conductor having a high stiffness such as iron, copper and 42 alloy as long as the electrical insulator is vapor-deposited or applied onto the surface thereof which is in contact with the sheet member 55. A ceramic material such as zirconia or a plastic plate containing a metal powder, for example, may also be used as long as the surface of the rigid plate 8 is electrically insulated. A conductor having a high stiffness such as iron even without an insulated surface layer may also be used as long as the conductor is provided with grooves or countersinks so as not to be in contact with the second buried conductors 9 having electrical conductivity but to be in contact only with the third buried conductors 14 not having electrical conductivity but having only thermal conductivity.

The components are brought into close contact with each other based on the foregoing arrangement, and then heat and pressure are applied in the atmosphere. Then, the adhesive layers 15 provided in the first- through fifth-level sheet members 51 through 55 are softened, so that the second resin board 4, the first- through fourth-level first resin boards 31 through 34 and the top rigid plate 8 are bonded together. In addition, the connecting lands 13 of the second resin board 4 and the first- through fourth-level first resin boards 31 through 34 are brought into mechanical contact with the second buried conductors 9 of the sheet members 5, thereby establishing electrical connection. That is, the application of pressure and heat makes the adhesive layers 15 softened and the conductive paste compressed so that the through holes are filled therewith with high density, and excellent contact with the connecting lands 13 is established. As a result, connection with low resistance is achieved. If the stacked structure is cooled and taken out after application of pressure and heat in a given period, a multi-level module in which the components are stacked and united is obtained.

Thereafter, solder balls 18 are bonded to the lands on the lower face of the second resin board 4, thereby obtaining a multi-level semiconductor module 1 (illustrated in FIG. 1) capable of being mounted on a mother board.

With the structure of the multi-level semiconductor module 1 of this embodiment described above, heat generated when the semiconductor devices 2 are driven are dissipated to the atmosphere (outside) through the first buried conductors 7, the second buried conductors 9, the third buried conductors 14 and the rigid plate 8. Accordingly, it is possible to prevent a warp of resin boards due to heat generation and a loss of signal transmission characteristic in driving. Such a warp and a loss hinder size reduction and increases of density and transmission speed. This structure also enables a longer lifetime of the module.

With a process of inserting the projections of the second buried conductors 9 into contacts or bringing the projections into contact with the tip of a burn-in board (not shown) after mounting of the semiconductor devices 2, a necessary electrical inspection and a necessary burn-in test are performed. Accordingly, only non-defective modules are used as products.

After the resin boards 3 and 4 and the sheet members 5 have been stacked, the second buried conductors 9 of the sheet members 5 are compressed and cured by application of pressure and heat. This establishes electrical connection between the second buried conductors 9 and the first buried conductors 7 and, in addition, resistance of the second buried conductors 9 is reduced.

In addition, since no loads are applied to the semiconductor devices 2 even under application of pressure, no failures occur in the semiconductor devices 2 and at the junctions thereof.

In the foregoing description, the first buried conductors 7 and the third buried conductors 14 are processed and formed for each level of the resin boards 3 and 4 and the sheet members 5. Alternatively, according to the present invention, after the resin boards 3 and 4 and the sheet members 5 have been stacked and before the rigid plate 8 is placed at the top, holes may be formed in the stacked structure using a mechanical drill or a carbon dioxide laser so that a conductive material or a plated conductor is vapor-deposited or applied onto the surface of the holes. As a method for attaching the top rigid plate 8 and the sheet member 55 to the stacked structure, the rigid plate 8 and the sheet member 55 may be stacked together before application of pressure and heat for bonding. Alternatively, the rigid plate 8 may be placed after the sheet member 55 has been attached and bonded to the stacked structure, or the sheet member 55 may be stacked and bonded after placement of the rigid plate 8.

Moreover, the degree of a warp of a stacked structure before the rigid plate 8 is placed thereon may be measured so that a rigid plate 8 capable of canceling this warp is selected. Specifically, to cancel a warp, it is sufficient to calculate a thickness and a material having a different thermal expansion coefficient according to the direction of the warp so as to select a rigid plate 8 using the calculated material and having the calculated thickness.

### Embodiment 2

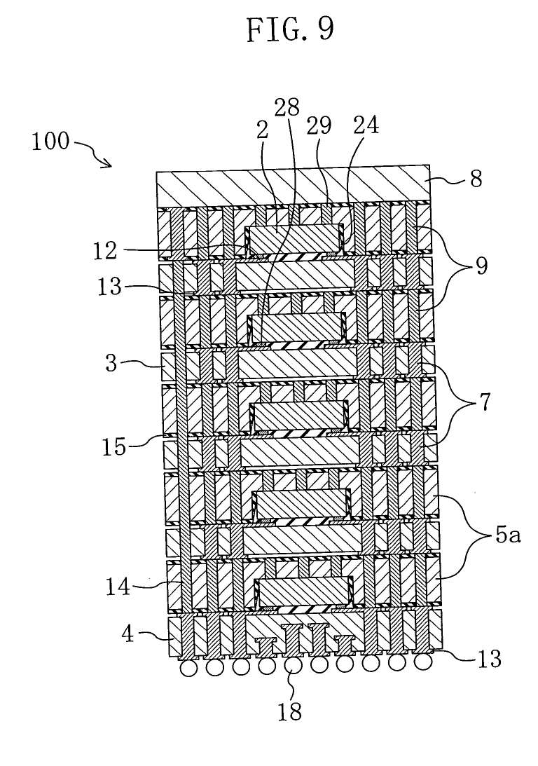

Hereinafter, a structure of a multi-level semiconductor module 100 according to a second embodiment of the present invention will be described with reference to FIG. 9. FIG. 9 is a cross-sectional view illustrating a structure of the multi-level semiconductor module 100 of the second embodiment.

As illustrated in FIG. 9, the multi-level semiconductor module 100 of this embodiment has a characteristic in which the thickness of sheet members 5a is larger than that of the sheet members 5 of the first embodiment and fourth buried conductors 29 formed in opening regions of the sheet members 5a are in contact with semiconductor devices 2. The other part of the structure is the same as that of the multi-level semiconductor module 1 of the first embodiment, and description thereof will be omitted.

A structure in which the fourth buried conductors 29 and the second buried conductors 9 are made of the same material has an advantage in which the module is easily fabricated. However, as the second buried conductors 9, the fourth buried conductors 29 do not need electrical connection, so that the fourth buried conductors 29 may be made of an electrically-insulating material as long as the fourth buried conductors 29 are made of a material having a high thermal conductivity. To form the sheet members 5a, openings 10 for the semiconductor devices 2 may be formed by, for example, polishing or a layer including an opening 10 and a layer not including an opening 10 may be stacked and bonded together by application of heat and pressure.

The multi-level semiconductor module of this embodiment has advantages similar to those described in the first embodiment. In addition, heat generated from the semiconductor devices 2 are dissipated from the surface by way of the fourth buried conductors 29, so that heat dissipation is further promoted.

### Embodiment 3

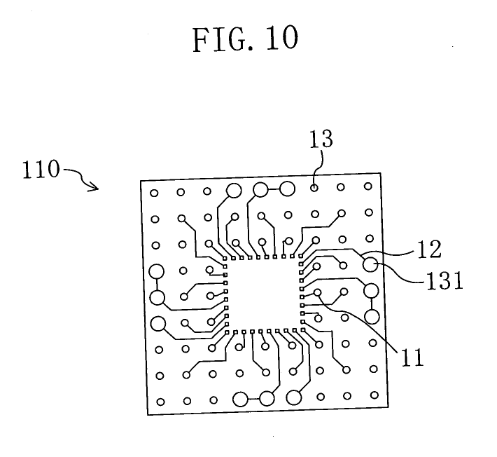

Hereinafter, a structure of a multi-level semiconductor module according to a third embodiment of the present invention will be described with reference to FIG. 10. FIG. 10 is a plan view illustrating a structure of a first resin board 110 for use in the multi-layer semiconductor module of the third embodiment.

As illustrated in FIG. 10, the multi-level semiconductor module of this embodiment has a characteristic in which first buried conductors 131 connected to predetermined electrode bumps on a semiconductor device 2 are larger than the other first buried conductors 7. The predetermined electrode bumps are, for example, input/output terminals requiring high-speed operation of the semiconductor device 2 and power-supply terminals. Though not shown, the diameter of first buried conductors (not shown) forming signal transmission lines connected to these terminals is increased, and the diameter of connecting lands 13 formed around the conductors is also increased.

Though not shown, the diameter of some of second buried conductors 9 in sheet members 5 associated with the connecting lands 13 in plan view is larger than that of the other conductors. The first resin boards 110 having the foregoing structure, a second resin board 4 and the sheet members 5 are stacked and pressure and heat are applied in the same manner as in the first embodiment, thereby obtaining a multi-level semiconductor module (not shown) of this embodiment.

In the multi-level semiconductor module of this embodiment, in a case where high-speed signals and analog signals need to be transmitted and received to/from semiconductor devices 2, the diameters of the first buried conductors 7 and the second buried conductors 9 forming a part of signal transmission lines for transmitting and receiving these signals are increased. Accordingly, electric signals are transmitted and received with stability. In addition, the resistance component of the transmission lines is reduced, so that heat generation inside the module caused by Joule heat is suppressed.

### Embodiment 4

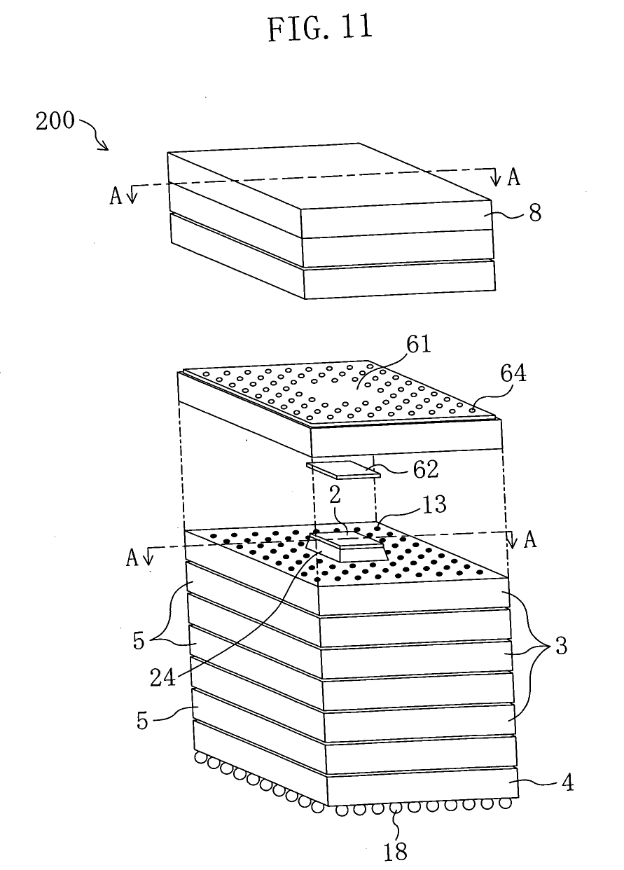

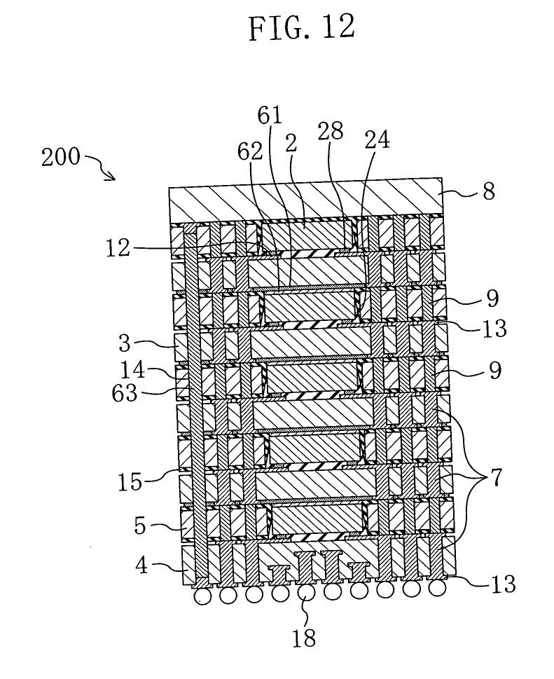

Hereinafter, a structure of a multi-level semiconductor module according to a fourth embodiment of the present invention will be described with reference to FIGS. 11 and 12. FIG. 11 is a perspective view schematically illustrating an overall structure of a multi-level semiconductor module 200 according to the fourth embodiment. FIG. 12 is a cross-sectional view taken along the line A-A in FIG. 11.

As illustrated in FIG. 11, the multi-level semiconductor module 200 of this embodiment has a structure in which graphite sheets 61 having a high conductivity in the lateral direction (i.e., in the direction parallel to the surfaces of resin boards and sheet members) are inserted between first and second resin boards 3 and 4 and sheet members 5. In addition, elastic bodies 62 having a high thermal conductivity interposed between the graphite sheets 61 and semiconductor devices 2 are provided in openings formed in the sheet members 5. The size of the elastic bodies 62 is smaller than or equal to that of the semiconductor devices 2 in plan view. The thickness of each of the elastic bodies 62 substantially corresponds to each of gaps between the sheet members 5 and the semiconductor devices 2.

In the multi-level semiconductor module 200 of this embodiment, a solid cooling member 63 is injected and cured in first buried conductors 7 and third buried conductors 14.

To avoid continuity to, for example, the first buried conductors 7, holes 64 (shown in FIG. 11) larger than the outer shape of connecting lands 13 on the first buried conductors 7 are formed in the graphite sheets 61. The other part of the structure is the same as that of the multi-level semiconductor module 1 of the first embodiment, and description thereof is omitted.

In the multi-level semiconductor module 200 of this embodiment, heat generated from the semiconductor devices 2 can be dissipated from the surfaces of the semiconductor devices 2 through the elastic bodies 62. In addition, the insertion of the graphite sheets having a thermal conductivity higher than that of the sheet members 5 in the lateral direction promotes thermal conduction to the cooling member 63, so that heat dissipation from a rigid plate 8 is further promoted. Moreover, the cooling member 63 itself enables forced cooling of heat generated from the semiconductor devices 2.

In this embodiment, only the graphite sheets 61 and the elastic bodies 62 need to be added to the semiconductor module 1. Accordingly, the module is easily fabricated.

In the foregoing structure, cooling water may be supplied as the cooling member 63 in the first buried conductors 7 and the third buried conductors 14 to be continuously circulated. In this case, it is necessary to prevent the cooling water from being leaked into portions outside through vias in secondary packaging. Alternatively, a heat pipe having a small diameter or a heat exchanger such as a Peltier device may be inserted.

In the first through fourth embodiments, a glass epoxy resin, for example, is mainly used for the first resin boards 3. However, the present invention is not limited to this. For example, a mixture containing 70 wt % to 95 wt %, both inclusive, of an inorganic filler and a thermosetting resin may be used for the first resin bases 16 forming the first and second resin boards 3 and 4 or the second resin bases forming the sheet members 5. The use of such materials allows thermal expansion coefficients to approach that of semiconductor devices, and thus occurrence of a warp is suppressed. In addition, in the first and fourth embodiments, the first buried conductors 7 and the second buried conductors 9 are arranged at the same pitch. Alternatively, the pitch of the first buried conductors 7 and the second buried conductors 9 may decrease toward a center portion of the board located near the semiconductor device 2. This arrangement enables heat generated from the semiconductor devices 2 to be more quickly dissipated from the rigid plate 8 by way of through vias.

What is claimed is:

1. A multi-level semiconductor module formed by alternately stacking resin boards and sheet members, each of the resin boards being provided with a semiconductor device, the multi-level semiconductor module comprising:
an electrically-insulating rigid body provided on one of the sheet members located at the top and having a heat dissipation efficiency higher than those of the resin boards and the sheet members; and
a through buried conductor penetrating the resin boards and the sheet members and being in contact with the electrically-insulating rigid body.

2. The multi-level semiconductor module of claim 1, wherein each of the resin boards includes: a mounting region on which a plurality of terminal electrodes connected to the semiconductor device are provided; and a peripheral region surrounding the mounting region,
first buried conductors penetrating the resin board and a wiring pattern electrically connecting the first buried conductors to the terminal electrodes are provided in the peripheral region of each of the resin boards,
each of the sheet members further includes a resin core having a thickness larger than that of the semiconductor device and having an opening region larger than the mounting region, and
a plurality of second buried conductors made of a conductor resin and located at positions corresponding to the positions of the terminal electrodes are provided in the resin core.

3. The multi-level semiconductor module of claim 2, wherein the resin boards and the sheet members are alternately stacked and bonded together in such a manner that the positions of the terminal electrodes of the resin boards match the positions of the second buried conductors in the sheet members, and
the through buried conductor penetrates one of the sheet members located at the top through one of the resin boards located at the bottom.

4. The multi-level semiconductor module of claim 2, wherein the second buried conductors and the through buried conductor are capable of being compressed and deformed by application of pressure, and
the through buried conductor is capable of being in contact with the electrically-insulating rigid body by application of pressure.

5. The multi-level semiconductor module of claim 2, wherein on a face of one of the resin boards located at the bottom opposite to a face thereof on which the semiconductor device is mounted, a plurality of external connection terminals for connecting the semiconductor device to external equipment are provided.

6. The multi-level semiconductor module of claim 2, wherein each of the sheet members further includes adhesive layers formed on both faces of the resin core and capable of being softened to be adhesive by application of heat, and
the second buried conductors protrude from the both faces of the resin core and penetrate the adhesive layers.

7. The multi-level semiconductor module of claim 2, wherein a thin plate medium having a thermal conductivity higher than that of the sheet members is interposed between each of the resin boards and an associated one of the sheet members, and
the thin plate medium has apertures each having a diameter larger than that of an associated one of the second buried conductors, at positions corresponding to the positions of the second buried conductors.

8. The multi-level semiconductor module of claim 2, wherein the opening region has a thickness substantially equal to that of the semiconductor device, and
a plurality of buried conductors having a high thermal conductivity are provided in the resin core in the opening region.

9. The multi-level semiconductor module of claim 2, wherein the pitches of the first and second buried conductors decrease toward the semiconductor device.

10. The multi-level semiconductor module of claim 2, wherein the semiconductor device includes a terminal, and
the diameter of each of some of the first and second buried conductors connected to the terminal is larger than that of each of the other first and second buried conductors not connected to the terminal.

11. The multi-level semiconductor module of claim 1, wherein a cooling medium is fixed to the inside of the through buried conductor.

12. A method for fabricating the multi-level semiconductor module of claim 1, the method comprising the step of applying pressure and heat to the electrically-insulating rigid body so that the resin boards and the sheet members are bonded together and are electrically connected to each other.

13. A method for fabricating the multi-level semiconductor module of claim 1, wherein the degree of a warp occurring in the resin boards in bonding the resin boards and the sheet members together by application of pressure and heat is previously obtained, and a material for the electrically-insulating rigid body is selected according to the amount.
